(19) United States
(12) Patent Application Publication
(10) Pub. No.: US 2014/0198931 A1
(43) Pub. Date: Jul. 17, 2014

(54) Digital Electronic Device and Method for Adjusting Signal Level of Digital Signal

(71) Applicant: Funai Electric Co., Ltd., Osaka (JP)

(72) Inventor: Akifumi MATSUMURA, Daito-shi (JP)

(73) Assignee: Funai Electric Co., Ltd., Osaka (JP)

(21) Appl. No.: 14/109,155

(22) Filed: Dec. 17, 2013

(30) Foreign Application Priority Data
Jan. 15, 2013 (JP) 2013-004864

(51) Int. Cl. H03G 7/00

(52) U.S. Cl. CPC H03G 7/007
USPC 381/107

(57) ABSTRACT

This digital electronic device includes an arithmetic portion calculating an adjustment coefficient employed to adjust a signal level calculated on the basis of a digital value detected by a detecting portion to not more than a possible output level that an output portion can output and an adjusting portion adjusting a digital signal on the basis of the adjustment coefficient calculated by the arithmetic portion such that the signal level becomes not more than the possible output level.

### BACKGROUND OF THE INVENTION

1. Field of the Invention

The present invention relates to a digital electronic device adjusting the output level of a digital signal and a method for adjusting the signal level of a digital signal.

2. Description of the Background Art

A digital electronic device adjusting the signal level of a digital signal to keep power constant is known in general.

Japanese Patent Laying-Open No. 2009-171524 discloses a high-frequency amplifier (digital electronic device) including an input level detecting portion detecting the amount of power (signal level) of a high-frequency signal (input signal) input to an input terminal, an amplifier amplifying an input signal, an output level detecting portion detecting the amount of power of a high-frequency signal (output signal) amplified by the amplifier and output from an output terminal, and a voltage variable attenuator (adjusting portion) attenuating (adjusting) the amount of power of the input signal when the amount of power of the output signal reaches at least a prescribed value. This digital electronic device is provided with a complicated circuit including a comparator comparing a detection result of the input level detecting portion with a detection result of the output level detecting portion, a feedback circuit providing feedback about a comparison result of the comparator, etc. in order for the voltage variable attenuator to adjust the amount of power of the input signal to keep power constant.

In the high-frequency amplifier (digital electronic device) disclosed in Japanese Patent Laying-Open No. 2009-171524, however, the complicated circuit including the comparator comparing the detection result of the input level detecting portion with the detection result of the output level detecting portion, the feedback circuit providing feedback about the comparison result of the comparator, etc. performs processing for adjusting the amount of power (signal level) of the input signal (processing for keeping power constant), whereby the circuit for adjusting the amount of power (signal level) of the input signal to keep power constant is disadvantageously complicated, and an apparatus is disadvantageously increased in size.

### SUMMARY OF THE INVENTION

The present invention has been proposed in order to solve the aforementioned problem, and an object of the present invention is to provide a digital electronic device and a method for adjusting the signal level of a digital signal each capable of simplifying a circuit for adjusting the signal level to keep power constant and downsizing an apparatus.

In order to attain the aforementioned object, a digital electronic device according to a first aspect of the present invention includes an output portion outputting a digital signal, a detecting portion detecting a digital value of the digital signal input to the output portion, an arithmetic portion calculating the signal level of the digital signal on the basis of the digital value detected by the detecting portion and calculating an adjustment coefficient employed to adjust the signal level that is calculated to not more than a possible output level that the output portion can output, and an adjusting portion adjusting the digital signal on the basis of the adjustment coefficient calculated by the arithmetic portion such that the signal level becomes not more than the possible output level.

The digital electronic device according to the first aspect of the present invention is configured as described above, whereby the digital signal is adjusted such that the signal level becomes not more than the possible output level on the basis of the adjustment coefficient calculated theoretically (by software) by the arithmetic portion, and hence no complicated circuit including a comparator comparing the single level of an input signal with the signal level of an output signal, a feedback circuit providing feedback about a comparison result of the comparator, etc. may be provided in order to adjust the signal level of the digital signal to keep power constant. Thus, a circuit for adjusting the signal level to keep power constant (a circuit including the adjusting portion) can be simplified, and an apparatus (the digital electronic device) can be downsized. Furthermore, according to the present invention, the adjustment coefficient is calculated by a software program to adjust the digital signal, whereby update processing of the software program can be easily performed by update of the software program or the like, and a constant power apparatus having excellent flexibility can be provided.

In the aforementioned digital electronic device according to the first aspect, the adjustment coefficient preferably includes compressibility employed to compress the signal level to not more than the possible output level, and the adjusting portion is preferably configured to compress the digital signal on the basis of the compressibility calculated by the arithmetic portion such that the signal level becomes not more than the possible output level. According to this structure, the digital signal is compressed on the basis of the compressibility calculated by the arithmetic portion, whereby the signal level of the digital signal can be easily adjusted to not more than the possible output level. Thus, power can be easily kept constant by software.

In this case, the digital electronic device preferably further includes a storage portion storing a value specific to the digital electronic device including a value corresponding to the possible output level, and the arithmetic portion is preferably configured to calculate the signal level on the basis of the digital value detected by the detecting portion and the value specific to the digital electronic device stored in the storage portion and calculate the compressibility employed to compress the signal level that is calculated to not more than the possible output level. According to this structure, the signal level and the compressibility can be easily calculated on the basis of the digital value detected by the detecting portion and the value specific to the digital electronic device stored in the storage portion. Furthermore, the contents stored in the storage portion are variously changed, whereby the contents can be flexibly accommodated to various digital electronic devices having different specifications.

The aforementioned digital electronic device including the storage portion storing the value specific to the digital electronic device preferably further includes a PWM conversion portion configured to convert a signal input from the adjusting portion to a PWM signal, an amplifying portion amplifying a signal input from the PWM conversion portion and outputting the signal to the output portion, and a power supply portion supplying power to the amplifying portion, and the value specific to the digital electronic device stored in the storage portion preferably includes at least one of the modulation factor of the PWM conversion portion, a power supply voltage input to the amplifying portion, the impedance of the output portion, the efficiency of the amplifying portion, and a maximum value of the amount of power that the power supply portion can output. According to this structure, the signal level and the compressibility appropriate for the digital electronic device can be calculated on the basis of the digital value detected by the detecting portion and at least one of the modulation factor of the PWM conversion portion, the power supply voltage input to the amplifying portion, the impedance of the output portion, the efficiency of the amplifying portion, and the maximum value of the amount of power that the power supply portion can output that are stored in the storage portion.

In the aforementioned digital electronic device including the adjusting portion compressing the digital signal, the adjusting portion is preferably configured to compress an excess portion of the digital signal whose signal level exceeds the possible output level on the basis of the compressibility calculated by the arithmetic portion such that the signal level of the excess portion becomes equal to the possible output level. According to this structure, the signal level of the excess portion becomes equal to the possible output level, and hence the signal level of the entirety of the digital signal including the excess portion can be easily adjusted to not more than the possible output level by software.

In this case, the adjusting portion is preferably configured not to compress a non-excess portion of the digital signal whose signal level does not exceed the possible output level and configured to compress the excess portion of the digital signal whose signal level exceeds the possible output level such that the signal level of the excess portion becomes equal to the possible output level. According to this structure, the non-excess portion of the digital signal whose signal level does not exceed the possible output level is not compressed, and hence a load on the adjusting portion can be reduced.

In the aforementioned digital electronic device including the adjusting portion compressing the digital signal, the adjusting portion is preferably configured to compress the entirety of the digital signal on the basis of the compressibility calculated by the arithmetic portion such that the signal level of the entirety of the digital signal becomes not more than the possible output level. According to this structure, the entirety of the digital signal is compressed, whereby the signal level of the entirety of the digital signal can be easily adjusted to not more than the possible output level by software without complicated processing, unlike the case where only part of the digital signal is compressed.

In this case, the adjusting portion is preferably configured to compress the gain of the entirety of the digital signal on the basis of the compressibility calculated by the arithmetic portion. According to this structure, the sound volume (gain) can be easily compressed, for example.

In the aforementioned digital electronic device configured to compress the entirety of the digital signal, the adjusting portion is preferably configured to compress the entirety of the digital signal such that the maximum value of the signal level after compression reaches the vicinity of the possible output level. According to this structure, an excessive reduction in an output (sound volume, for example) from the output portion resulting from excessive compression of the digital signal can be suppressed.

In the aforementioned digital electronic device configured to compress the entirety of the digital signal, the adjusting portion is preferably configured to compress the entirety of the digital signal such that the signal waveform of the digital signal before compression and the signal waveform of the digital signal after compression have shapes corresponding to each other. According to this structure, the proportion of the signal waveform of the digital signal before and after compression is maintained, and hence a change in the characteristics of the digital signal can be suppressed.

In the aforementioned digital electronic device including the adjusting portion compressing the digital signal, the adjusting portion is preferably configured to compress an excess portion of the digital signal whose signal level exceeds the possible output level on the basis of the compressibility calculated by the arithmetic portion such that the signal level of the excess portion becomes not more than the possible output level. According to this structure, a portion other than the excess portion is not compressed, and hence an excessive reduction in the signal level resulting from compression of a portion (the portion other than the excess portion) normally not need to be compressed can be suppressed.

In this case, the adjusting portion is preferably configured not to compress a non-excess portion of the digital signal whose signal level does not exceed the possible output level and configured to compress the entirety of the excess portion of the digital signal whose signal level exceeds the possible output level. According to this structure, the non-excess portion of the digital signal whose signal level does not exceed the possible output level is not compressed, and hence a load on the adjusting portion can be reduced.

In the aforementioned digital electronic device configured to compress the excess portion whose signal level exceeds the possible output level, the adjusting portion is preferably configured to compress the entirety of the excess portion of the digital signal whose signal level exceeds the possible output level on the basis of the compressibility calculated by the arithmetic portion such that the signal waveform of the digital signal before compression and the signal waveform of the digital signal after compression have shapes corresponding to each other. According to this structure, the proportion of the signal waveform of the digital signal before and after compression is maintained, and hence a change in the characteristics of the digital signal can be suppressed.

The aforementioned digital electronic device according to the first aspect preferably further includes an amplifying portion amplifying a signal input from the adjusting portion and outputting the signal to the output portion and a power supply portion supplying power to the amplifying portion, and the possible output level preferably includes a value corresponding to the maximum value of the amount of power that the power supply portion can output. According to this structure, a large signal (large sound volume, for example) can be output from the output portion within the range of the amount of power that the power supply portion can output.

A method for adjusting the signal level of a digital signal according to a second aspect of the present invention includes steps of detecting a digital value of the digital signal, calculating the signal level of the digital signal on the basis of the digital value that is detected and calculating an adjustment coefficient employed to adjust the signal level that is calculated to not more than a prescribed possible output level, and adjusting the digital signal on the basis of the adjustment coefficient that is calculated such that the signal level becomes not more than the prescribed possible output level.

The method for adjusting the signal level of a digital signal according to the second aspect of the present invention is configured as described above, whereby the digital signal is adjusted such that the signal level becomes not more than the prescribed possible output level on the basis of the adjustment coefficient calculated theoretically (by software), and hence no complicated circuit including a comparator etc. providing feedback about a detection result of the single level of an input signal and a detection result of the signal level of an output signal and comparing the same may be provided in order to adjust the signal level of the digital signal to keep power constant. Thus, the method for adjusting the signal level of a digital signal capable of simplifying a circuit for adjusting the signal level to keep power constant and downsizing an apparatus can be provided. Furthermore, according to the present invention, the adjustment coefficient is calculated by a software program to adjust the digital signal, whereby the method for adjusting the signal level of a digital signal capable of easily performing update processing of the software program by update of the software program or the like and having excellent flexibility can be provided.

In the aforementioned method for adjusting the signal level of a digital signal according to the second aspect, the step of calculating the adjustment coefficient preferably includes a step of calculating the signal level of the digital signal on the basis of the digital value that is detected and calculating compressibility employed to compress the signal level that is calculated to not more than the prescribed possible output level, and the step of adjusting the digital signal preferably includes a step of compressing the digital signal on the basis of the compressibility that is calculated such that the signal level becomes not more than the prescribed possible output level. According to this structure, the digital signal is compressed on the basis of the compressibility that is calculated, whereby the signal level of the digital signal can be easily adjusted to not more than the prescribed possible output level. Thus, power can be easily kept constant by software.

In this case, the step of calculating the compressibility preferably includes a step of calculating the signal level on the basis of the digital value that is detected and a value specific to a digital electronic device including a value corresponding to the prescribed possible output level that is stored and calculating the compressibility employed to compress the signal level that is calculated to not more than the prescribed possible output level. According to this structure, the signal level and the compressibility can be easily calculated on the basis of the digital value that is detected and the value specific to the digital electronic device stored in the storage portion. Furthermore, the contents stored in the storage portion are variously changed, whereby the contents can be flexibly accommodated to various digital electronic devices having different specifications.

In the aforementioned method for adjusting the signal level of a digital signal including the step of calculating the compressibility, the step of compressing the digital signal preferably includes a step of compressing an excess portion of the digital signal whose signal level exceeds the prescribed possible output level on the basis of the compressibility that is calculated such that the signal level of the excess portion becomes equal to the prescribed possible output level. According to this structure, the signal level of the excess portion becomes equal to the prescribed possible output level, and hence the signal level of the entirety of the digital signal including the excess portion can be easily adjusted to not more than the prescribed possible output level by software.

In the aforementioned method for adjusting the signal level of a digital signal including the step of calculating the compressibility, the step of compressing the digital signal preferably includes a step of compressing the entirety of the digital signal on the basis of the compressibility that is calculated such that the signal level of the entirety of the digital signal becomes not more than the prescribed possible output level. According to this structure, the entirety of the digital signal is compressed, whereby the signal level of the entirety of the digital signal can be easily adjusted to not more than the prescribed possible output level by software without complicated processing, unlike the case where only part of the digital signal is compressed.

In the aforementioned method for adjusting the signal level of a digital signal including the step of calculating the compressibility, the step of compressing the digital signal preferably includes a step of compressing an excess portion of the digital signal whose signal level exceeds the prescribed possible output level on the basis of the compressibility that is calculated such that the signal level of the excess portion becomes not more than the prescribed possible output level. According to this structure, a portion other than the excess portion is not compressed, and hence an excessive reduction in the signal level resulting from compression of a portion (the portion other than the excess portion) normally not need to be compressed can be suppressed.

According to the present invention, as hereinabove described, the circuit for adjusting the signal level to keep power constant can be simplified, and the apparatus can be downsized.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a block diagram showing the overall structure of an audio system according to a first embodiment of the present invention;

FIG. 2 is an image diagram showing the signal waveform before and after compression of an audio signal output from the audio system according to the first embodiment of the present invention;

FIG. 3 is an image diagram for illustrating a method (computation theory) for calculating the compressibility of the signal level of an audio signal in the audio system according to the first embodiment of the present invention;

FIG. 4 is a table showing a list of theoretical values (calculated values) calculated by the computation theory employed in the audio system according to the first embodiment of the present invention;

FIG. 5 is a table showing a list of measured values corresponding to the theoretical values in FIG. 4;

FIG. 6 is an image diagram showing the signal waveform before and after compression of an audio signal output from an audio system according to a second embodiment of the present invention; and

FIG. 7 is an image diagram showing the signal waveform before and after compression of an audio signal output from an audio system according to a third embodiment of the present invention.

### DESCRIPTION OF THE PREFERRED EMBODIMENTS

Embodiments of the present invention are hereinafter described with reference to the drawings.

### First Embodiment

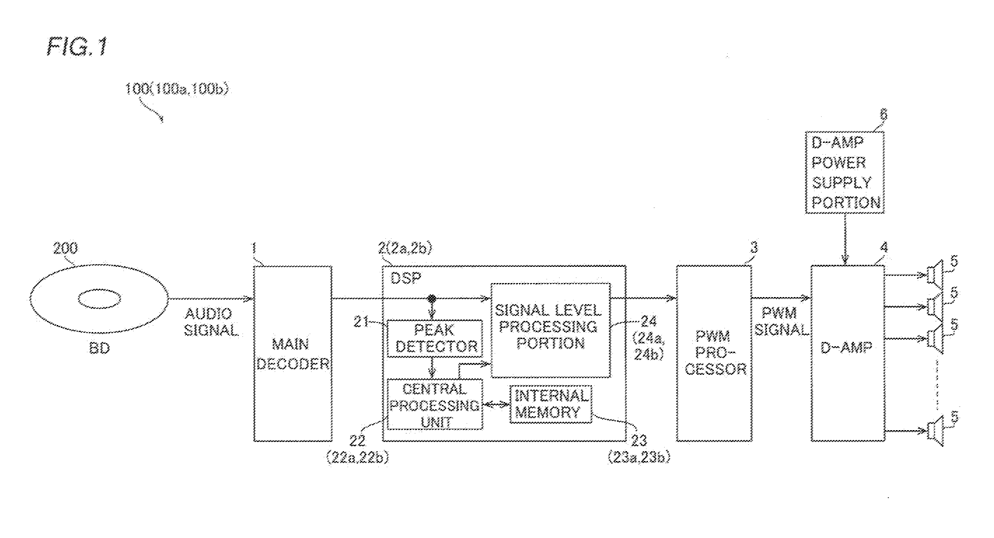

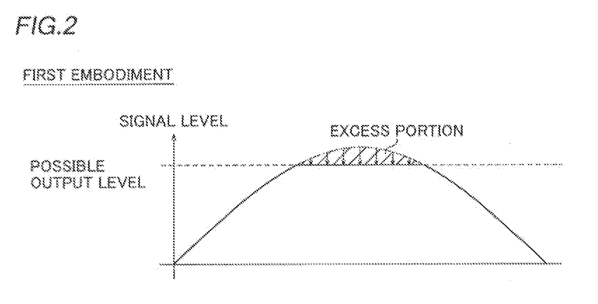

The structure of an audio system 100 according to a first embodiment of the present invention is now described with reference to FIGS. 1 and 2. This audio system 100 is a digital electronic device configured to be capable of outputting and reproducing audio data (digital data) recorded in a disk-type recording medium such as a BD (Blu-ray Disc) 200.

As shown in FIG. 1, the audio system 100 includes a decoder 1, a DSP (digital signal processor) 2 connected to the decoder 1, a PWM (pulse width modulation) processor 3 connected to the DSP 2, a D-AMP (digital amplifier) 4 connected to the PWM processor 3, a plurality of speakers 5 connected to the D-AMP 4, and a D-AMP power supply portion 6 connected to the D-AMP 4. The PWM processor 3 is an example of the “PWM conversion portion” in the present invention. The speakers 5 are examples of the “output portion” in the present invention. The D-AMP 4 and the D-AMP power supply portion 6 are examples of the “amplifying portion” and the “power supply portion” in the present invention, respectively.

The decoder 1 is provided to decode an audio signal (digital signal) corresponding to audio data stored in the BD 200. The DSP 2 is provided to perform various types of processing (processing for compressing a signal level described later, for example) on the audio signal input from the decoder 1. The PWM processor 3 is provided to convert the audio signal input from the DSP 2 to a PWM signal. The D-AMP 4 is provided to amplify the PWM signal input from the PWM processor 3. The plurality of speakers 5 are configured to output sound to the outside on the basis of the PWM signal amplified by the D-AMP 4. The D-AMP power supply portion 6 is provided to supply power to the D-AMP 4.

According to the first embodiment, the DSP 2 includes a peak detector 21 connected to the output of the decoder 1, a central processing unit 22 connected to the output of the peak detector 21, an internal memory 23 connected to the central processing unit 22, and a signal level processing portion 24 connected to the output of the central processing unit 22 and connected to the output of the decoder 1. The peak detector 21, the central processing unit 22, the internal memory 23, and the signal level processing portion 24 are examples of the “detecting portion”, the “arithmetic portion”, the “storage portion”, and the “adjusting portion” in the present invention, respectively.

The peak detector 21 is configured to detect a digital value Xₙ (n is a number allocated to each of the plurality of speakers 5 for convenience sake) of the audio signal (digital signal) output from the decoder 1. The central processing unit 22 is configured to calculate the signal level Vₙ of an audio signal corresponding to the sound output from each of the plurality of speakers 5 on the basis of the digital value Xₙ detected by the peak detector 21 and calculate an adjustment coefficient for adjusting the calculated signal level Vₙ to not more than a prescribed possible output level (a value corresponding to a maximum value W_{L} of the amount of power that the D-AMP power supply portion 6 can actually output: see a dotted line in FIG. 2). Specifically, the central processing unit 22 is configured to calculate compressibility C_{L} for compressing the signal level Vₙ to not more than the prescribed possible output level.

The internal memory 23 stores a software program executed by the central processing unit 22, various values (values specific to the audio system 100) that the central processing unit 22 employs to calculate the compressibility C_{L}, etc. The internal memory 23 stores the modulation factor m of the PWM processor 3, a power supply voltage V_{D} input to the D-AMP 4, the impedance Rₙ of each of the speakers 5, the efficiency E_{D} of the D-AMP 4, the maximum value W_{L} of the amount of power that the D-AMP power supply portion 6 can actually output, etc. for example. Thus, the central processing unit 22 is configured to theoretically calculate the compressibility C_{L} on the basis of the digital value Xₙ detected by the peak detector 21 and the aforementioned modulation factor m, power supply voltage V_{D}, impedance Rₙ, efficiency E_{D}, and maximum value W_{L} of the amount of power stored in the internal memory 23. A method for calculating the compressibility C_{L} is described later in detail.

The signal level processing portion 24 is configured to include a multiplier. This signal level processing portion 24 is configured to adjust the signal level Vₙ of the audio signal to not more than the prescribed possible output level (the value corresponding to the maximum value W_{L} of the amount of power that the D-AMP power supply portion 6 can actually output: see the dotted line in FIG. 2) on the basis of an adjustment coefficient (compressibility C_{L}) calculated by the central processing unit 22. Specifically, the signal level processing portion 24 is configured to compress the signal level Vₙ of the audio signal to not more than the prescribed possible output level by multiplying the digital value Xₙ of the audio signal input to the signal level processing portion 24 by the square root √C_{L} of the compressibility C_{L}. More specifically, the signal level processing portion 24 is configured to compress an excess portion (see a shaded area) of the audio signal whose signal level exceeds the possible output level (see a dotted straight line) on the basis of the compressibility C_{L} calculated by the central processing unit 22 such that the signal level of the excess portion becomes equal to the possible output level, as shown in FIG. 2. In FIG. 2, the signal waveform of the audio signal before compression is indicated by an alternate long and short dash line, and the signal waveform after compression is indicated by a solid line.

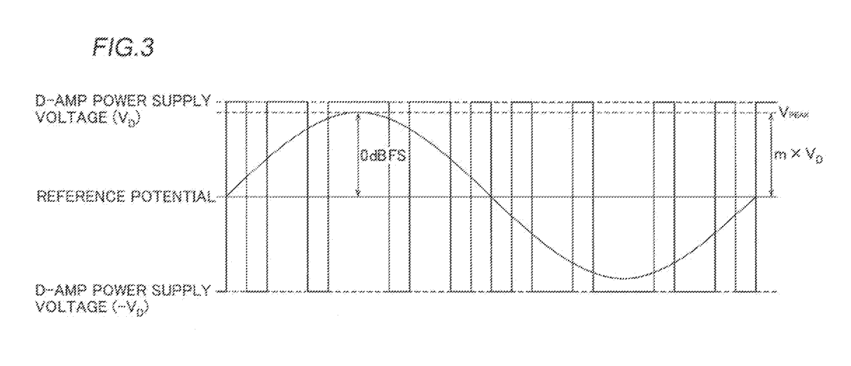

The method (computation theory) for calculating the compressibility of the audio signal in the audio system 100 according to the first embodiment of the present invention is now described with reference to FIG. 3.

First, the central processing unit 22 calculates the signal level Vₙ of the audio signal at the time when the peak detector 21 detects the digital value Xₙ (n is a number allocated to each of the plurality of speakers 5 for convenience sake) of the audio signal (digital signal) output from the decoder 1 at a certain point of time on the basis of the following expression (1).

$${V}_{n} [ V ] = {V}_{PEAK} \times \frac{{X}_{n}}{{X}_{FS }} \qquad ( 1 )$$

In the aforementioned expression (1), X_{FS} represents a digital full scale value (a value corresponding to 0 dBFS in FIG. 3) of the quantized audio signal (digital signal). When the audio signal is quantized at 8 bits, for example, the digital full scale value of the audio signal is 2⁸=256. In the aforementioned expression (1), V_{PEAK} represents a peak value (see FIG. 3) of the signal level of the audio signal output from the decoder 1.

The central processing unit 22 calculates the peak value V_{PEAK} of the signal level of the audio signal in the aforementioned expression (1) on the basis of the following expression (2).

V_{PEAK}[V]=m×V_{D} (2)

In the aforementioned expression (2), m represents the modulation factor of the PWM processor 3. V_{D} represents a voltage value of power supplied to the D-AMP 4 from the D-AMP power supply portion 6. These values (m and V_{D}) are previously stored in the internal memory 23 connected to the central processing unit 22.

When the aforementioned expression (1) is expressed using a ratio rₙ to the peak value of the signal level of the audio signal (a ratio to a full scale value of a digital value at a certain point of time) instead of the digital value Xₙ of the audio signal, the aforementioned expression (1) is expressed as the following expression (3). The ratio rₙ is expressed as the following expression (4) using the digital value Xₙ.

$$\begin{matrix}{V}_{n} [ V ] = {V}_{PEAK} \times {10}^{\frac{{r}_{n}}{20}} & ( 3 ) \\ {r}_{n} [ dB ] = 20 \times log ( \frac{{X}_{n}}{{X}_{FS}} ) & ( 4 )\end{matrix}$$

When calculating the signal level Vₙ of the audio signal output from the decoder 1 at a certain point of time on the basis of the aforementioned expression (1) or (3), the central processing unit 22 calculates a maximum power consumption W_{n(MAX)} of each of the speakers 5 at a certain point of time on the basis of the following expression (5) using the signal level Vₙ. Then, the central processing unit 22 sums the maximum power consumptions W_{n(MAX)} of all the plurality of speakers 5 calculated on the basis of the following expression (5) and calculates the sum W_{T} of the power consumptions of the speakers 5 on the basis of the following expression (6).

$$\begin{matrix}{W}_{n ( MA X )} [ W ] = \frac{{V}_{n}^{2}}{{R}_{n}} & ( 5 ) \\ {W}_{T} [ W ] = ( \frac{{V}_{1}^{2}}{{R}_{1}} + \frac{{V}_{2}^{2}}{{R}_{2}} + … ) \times \frac{1}{{E}_{D}} & ( 6 )\end{matrix}$$

In the aforementioned expression (5), Rₙ represents the impedance of each of the speakers 5. In the aforementioned expression (6), E_{D} represents the efficiency of the D-AMP 4. These values (Rₙ and E_{D}) are previously stored in the internal memory 23 connected to the central processing unit 22.

When the sum W_{T} of the power consumptions calculated on the basis of the aforementioned expression (6) is at least the maximum value W_{L} of the amount of power that the D-AMP power supply portion 6 can actually output, the D-AMP power supply portion 6 is cut off, and sound cannot be normally output from the speakers 5 if the audio system 100 tries to output the audio signal without any change. Therefore, it is necessary to compress the signal level of the audio signal by the signal level processing portion 24 in order to limit W_{T} to not more than W_{L}. Thus, the central processing unit 22 calculates the compressibility C_{L} of the signal level of the audio signal on the basis of the following expression (7).

$${C}_{L} = \frac{{W}_{L}}{{W}_{T}} \qquad ( 7 )$$

According to the aforementioned expressions (6) and (7), the maximum value W_{L} of the amount of power that the D-AMP power supply portion 6 can actually output is expressed as the following expression (8).

$$\begin{matrix}{W}_{L} [ W ] = {C}_{L} \times {W}_{T} \\ = {C}_{L} \times ( \frac{{V}_{1}^{2}}{{R}_{1}} + \frac{{V}_{2}^{2}}{{R}_{2}} + … ) \times \frac{1}{{E}_{D}} \\ = ( \frac{{( \sqrt{{C}_{L}} \times {V}_{1} )}^{2}}{{R}_{1}} + \frac{{( \sqrt{{C}_{L}} \times {V}_{2} )}^{2}}{{R}_{2}} + … ) \times \frac{1}{{E}_{D}} \\ = ( \begin{matrix}\frac{{( \sqrt{{C}_{L}} \times m \times {V}_{D} \times \frac{{X}_{1}}{{X}_{FS}} )}^{2}}{{R}_{1}} + \\ \frac{{( \sqrt{{C}_{L}} \times m \times {V}_{D} \times \frac{{X}_{2}}{{X}_{FS}} )}^{2}}{{R}_{2}} + … \end{matrix} ) \times \frac{1}{{E}_{D}}\end{matrix} \qquad ( 8 )$$

The aforementioned expression (8) shows that, in order to limit W_{T} to not more than W_{L}, it is appropriate to compress the signal level of the audio signal by performing processing for multiplying the digital value Xₙ of the audio signal by the square root √C_{L} of the compressibility C_{L} by the signal level processing portion 24 when the sum W_{T} of the power consumptions is at least the maximum value W_{L} of the amount of power that the D-AMP power supply portion 6 can actually output.

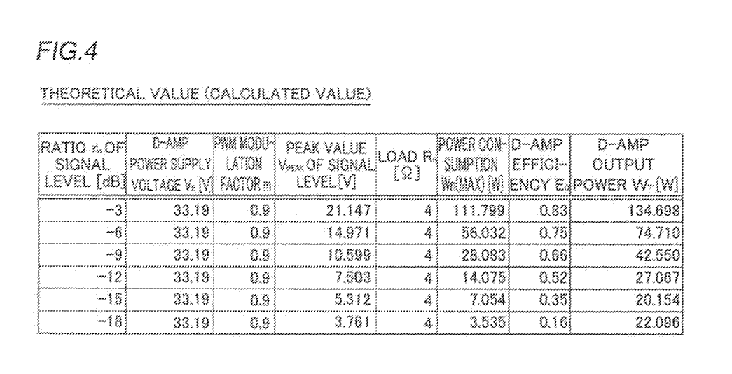

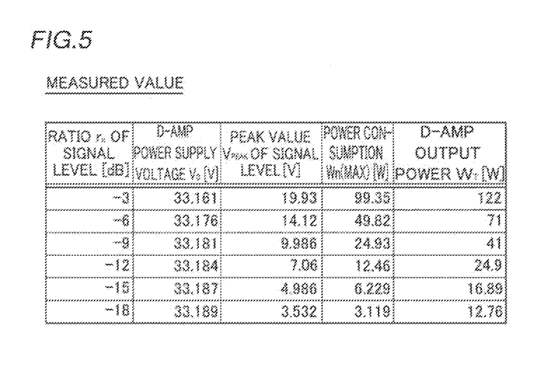

An experiment conducted for confirming the computation theory (see the aforementioned expressions (1) to (8)) employed to calculate the compressibility C_{L} of the signal level of the audio signal in the audio system 100 according to the first embodiment of the present invention is now described with reference to FIGS. 4 and 5.

In this experiment, setting the modulation factor m of the PWM processor 3 of the audio system 100 according to the first embodiment to 0.9, the power supply voltage V_{D} of the D-AMP power supply portion 6 of the audio system 100 according to the first embodiment to 33.19 V, and the impedance (load) Rₙ of each of the speakers 5 of the audio system 100 according to the first embodiment to 4, the theoretical values (calculated values) of the peak value V_{PEAK} of the signal level, the maximum power consumption W_{n(MAX)} of each of the speakers 5, and the output power W_{T} of the D-AMP power supply portion 6 were calculated on the basis of the aforementioned expressions (1) to (8). In this calculation, the efficiency E_{D} of the D-AMP 4 is set to 0.83 when the ratio rₙ to the peak value of the signal level of the audio signal is −3 dB, the efficiency E_{D} of the D-AMP 4 is set to 0.75 when the ratio rₙ to the peak value of the signal level of the audio signal is −6 dB, the efficiency E_{D} of the D-AMP 4 is set to 0.66 when the ratio rₙ to the peak value of the signal level of the audio signal is −9 dB, the efficiency E_{D} of the D-AMP 4 is set to 0.52 when the ratio rₙ to the peak value of the signal level of the audio signal is −12 dB, the efficiency E_{D} of the D-AMP 4 is set to 0.35 when the ratio rₙ to the peak value of the signal level of the audio signal is −15 dB, and the efficiency E_{D} of the D-AMP 4 is set to 0.16 when the ratio rₙ to the peak value of the signal level of the audio signal is −18 dB. FIG. 4 shows a list of these calculation results (theoretical values).

Then, a real machine corresponding to the audio system 100 according to the first embodiment is prepared, and the aforementioned values (the power supply voltage V_{D} of the D-AMP power supply portion, the peak value V_{PEAK} of the signal level, the maximum power consumption W_{n(MAX)} of each of the speakers, and the output power W_{T} of the D-AMP power supply portion) corresponding to the theoretical values in FIG. 4 in each case where the ratio rₙ to the peak value of the signal level of the audio signal is −3 dB, −6 dB, −9 dB, −12 dB, −15 dB, and −18 dB were actually measured with the real machine. FIG. 5 shows a list of these measurement results (measured values).

Comparison of FIG. 4 with FIG. 5 showed that at the time of high output when it was necessary to compress the signal level (when the ratio rₙ of the signal level was at least −15 dB: see rows higher than the lowermost rows in FIGS. 4 and 5), errors between the theoretical values and the measured values were relatively small, so that the computation theory of the aforementioned expressions (1) to (8) was almost correct. When the theoretical value and the measured value of the output voltage W_{T} of the D-AMP 4 (the sum of the power consumptions of the speakers 5) in the case where rₙ was −3 dB were compared, for example, the theoretical value was 134.698 (see FIG. 4), and the measured value was 122 (see FIG. 5). Therefore, the output voltage W_{T} of the D-AMP 4 could be predicted with about 90% accuracy in the case where rₙ was −3 dB.

On the other hand, the comparison of FIG. 4 with FIG. 5 showed that at the time of low output (when the ratio rₙ of the signal level was −18 dB: see the lowermost rows in FIGS. 4 and 5), errors between the theoretical values and the measured values were relatively large. When the theoretical value and the measured value of the output voltage W_{T} of the D-AMP 4 (the sum of the power consumptions of the speakers 5) in the case where rₙ was −18 dB were compared, for example, the theoretical value was 22.096 (see FIG. 4), and the measured value was 12.76 (see FIG. 5). Therefore, the output voltage W_{T} of the D-AMP 4 could be predicted with only about 57% accuracy in the case where rₙ was −18 dB. This is conceivably because at the time of low output, the efficiency E_{D} of the D-AMP 4 is extremely reduced (as shown in FIG. 4, the efficiency E_{D} is 0.16 in the case where the ratio rₙ of the signal level is −18 dB). According to the first embodiment, however, it is not necessary to compress the signal level at the time of low output, and hence the influence of the errors at the time of low output on the overall system is conceivably small.

According to the first embodiment, as hereinabove described, the audio system 100 is provided with the central processing unit 22 calculating the signal level Vₙ of the audio signal (digital signal) on the basis of the digital value Xₙ detected by the peak detector 21 and calculating the compressibility (adjustment coefficient) C_{L} for compressing (adjusting) the calculated signal level Vₙ to not more than the possible output level (the value corresponding to the maximum value W_{L} of the amount of power that the D-AMP power supply portion 6 can actually output: see the dotted line in FIG. 2) and the signal level processing portion 24 compressing the audio signal such that the signal level Vₙ becomes not more than the possible output level on the basis of the compressibility C_{L} calculated by the central processing unit 22. Thus, the audio signal is adjusted such that the signal level Vₙ becomes not more than the possible output level on the basis of the compressibility C_{L} calculated theoretically (by software) by the central processing unit 22, and hence no complicated circuit including a comparator comparing the single level of an input signal with the signal level of an output signal, a feedback circuit providing feedback about a comparison result of the comparator, etc. may be provided in order to adjust the signal level Vₙ of the audio signal to keep power constant. Thus, a circuit for adjusting the signal level Vₙ to keep power constant (the DSP 2 including the signal level processing portion 24) can be simplified, and an apparatus (the audio system 100) can be downsized. Furthermore, according to the first embodiment, the adjustment coefficient C_{L} is calculated by the software program to adjust the digital signal, whereby update processing of the software program can be easily performed by update of the software program or the like, and a constant power apparatus having excellent flexibility can be provided.

According to the first embodiment, as hereinabove described, the central processing unit 22 is configured to calculate the signal level Vₙ on the basis of the digital value Xₙ detected by the peak detector 21 and the values specific to the audio system 100 stored in the internal memory 23 (the modulation factor m of the PWM processor 3, the power supply voltage V_{D} input to the D-AMP 4, the impedance Rₙ of each of the speakers 5, the efficiency E_{D} of the D-AMP 4, the maximum value W_{L} of the amount of power that the D-AMP power supply portion 6 can actually output, etc.) and calculate the compressibility C_{L} for compressing the calculated signal level Vₙ to not more than the possible output level. Thus, the signal level Vₙ and the compressibility C_{L} appropriate for the audio system 100 can be easily calculated on the basis of the digital value Xₙ detected by the peak detector 21 and the specific values stored in the internal memory 23. Furthermore, the contents stored in the internal memory 23 are variously changed, whereby the contents can be flexibly accommodated to various audio systems 100 having different specifications.

According to the first embodiment, as hereinabove described, the signal level processing portion 24 is configured to compress the excess portion (see the shaded area in FIG. 2) of the audio signal whose signal level Vₙ exceeds the possible output level on the basis of the compressibility C_{L} calculated by the central processing unit 22 such that the signal level Vₙ of the excess portion becomes equal to the possible output level. Thus, the signal level Vₙ of the excess portion becomes equal to the possible output level, and hence the signal level Vₙ of the entirety of the audio signal including the excess portion can be easily adjusted to not more than the possible output level by software.

According to the first embodiment, as hereinabove described, the signal level processing portion 24 is configured not to compress a non-excess portion of the audio signal whose signal level does not exceed the possible output level and configured to compress the excess portion of the audio signal whose signal level exceeds the possible output level such that the signal level of the excess portion becomes equal to the possible output level. Thus, the non-excess portion of the audio signal whose signal level does not exceed the possible output level is not compressed, and hence a load on the signal level processing portion 24 can be reduced.

According to the first embodiment, as hereinabove described, the audio system 100 is provided with the D-AMP 4 amplifying the signal input from the signal level processing portion 24 and outputting the amplified signal to the speakers 5 and the D-AMP power supply portion 6 supplying power to the D-AMP 4, and the possible output level is set to the value corresponding to the maximum value of the amount of power that the D-AMP power supply portion 6 can output. Thus, a large signal (large sound volume) can be output from the speakers 5 within the range of the amount of power that the D-AMP power supply portion 6 can output.

### Second Embodiment

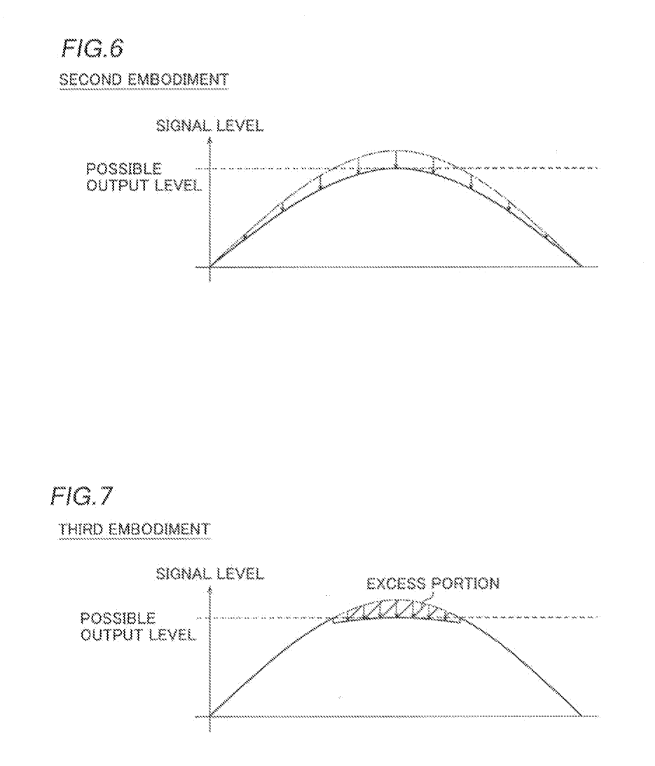

The structure of an audio system 100a according to a second embodiment of the present invention is now described with reference to FIGS. 1 and 6. In this second embodiment, the entirety of a digital signal is compressed such that the signal level of the entirety of the digital signal becomes not more than a possible output level, unlike the aforementioned first embodiment in which the excess portion (see the shaded area in FIG. 2) of the digital signal whose signal level exceeds the possible output level is compressed such that the signal level of the excess portion becomes equal to the possible output level.

As shown in FIG. 1, according to the second embodiment, a DSP 2a of the audio system 100a includes a peak detector 21 connected to the output of a decoder 1, a central processing unit 22a connected to the output of the peak detector 21, an internal memory 23a connected to the central processing unit 22a, and a signal level processing portion 24a connected to the output of the central processing unit 22a and connected to the output of the decoder 1, similarly to the aforementioned first embodiment. The central processing unit 22a, the internal memory 23a, and the signal level processing portion 24a are examples of the “arithmetic portion”, the “storage portion”, and the “adjusting portion” in the present invention, respectively.

The peak detector 21 is configured to detect a digital value Xₙ of an audio signal (digital signal) output from the decoder 1, similarly to the aforementioned first embodiment. The central processing unit 22a is configured to calculate compressibility C_{L} for compressing the signal level Vₙ of the audio signal to not more than a prescribed possible output level (see a dotted line in FIG. 6) on the basis of the digital value Xₙ detected by the peak detector 21 and values specific to the audio system 100a stored in the internal memory 23a, similarly to the aforementioned first embodiment. The internal memory 23a stores a software program executed by the central processing unit 22a etc. in addition to the values specific to the audio system 100a such as the modulation factor m of a PWM processor 3, a power supply voltage V_{D} input to a D-AMP 4, the impedance Rₙ of each of speakers 5, the efficiency E_{D} of the D-AMP 4, and the maximum value W_{L} of the amount of power that a D-AMP power supply portion 6 can actually output.

According to the second embodiment, the signal level processing portion 24a includes a volume control unit configured to adjust the sound volume (gain) of the audio signal output from the D-AMP 4. This signal level processing portion 24a is configured change a current setting value A_{old} of the sound volume to a new setting value A_{new} calculated on the basis of the following expression (9) on the basis of an adjustment coefficient (compressibility C_{L}) calculated by the central processing unit 22a.

new setting value A_{new}[dB]=current setting value A_{old}[dB]+20 log(√C_{L}) (9)

Thus, according to the second embodiment, the signal level processing portion 24a is configured to compress the entirety of the audio signal such that the signal level of the entirety of the audio signal becomes not more than the possible output level on the basis of the compressibility C_{L} calculated by the central processing unit 22a, as shown in FIG. 6. In FIG. 6, the signal waveform of the audio signal before compression is indicated by an alternate long and short dash line, and the signal waveform after compression is indicated by a solid line.

According to the second embodiment, the signal waveform (see the alternate long and short dash line) of the audio signal before compression and the signal waveform (see the solid line) of the audio signal after compression have curves (sinusoidal curves) of shapes corresponding to each other throughout the figure in a horizontal axis direction, as shown in FIG. 6. In other words, according to the second embodiment, the signal level processing portion 24a is configured to compress the sound volume (gain) of the entirety of the audio signal such that the signal level of the entirety of the audio signal becomes not more than the possible output level and the proportion of the signal waveform of the entirety of the audio signal is maintained before compression and after compression. Furthermore, the signal level processing portion 24a is configured to compress the entirety of the audio signal such that the maximum value of the signal level after compression reaches the vicinity of the possible output level. According to the second embodiment, processing for compressing the gain described above may be performed constantly. When the processing for compressing the gain is performed for a given length of time, the processing for compressing the gain may be stopped unless the sum W_{T} of the power consumptions of the speakers 5 calculated by the central processing unit 22a within the given length of time becomes at least the maximum value W_{L} of the amount of power that the D-AMP power supply portion 6 can actually output. When the sum W_{T} of the power consumptions of the speakers 5 becomes at least the maximum value W_{L} of the amount of power that the D-AMP power supply portion 6 can actually output, the processing for compressing the gain may be restarted.

According to the second embodiment, as hereinabove described, the signal level processing portion 24a is configured to compress the entirety of the audio signal (digital signal) on the basis of the compressibility C_{L} calculated by the central processing unit 22a such that the signal level Vₙ of the entirety of the audio signal becomes not more than the possible output level (see the dotted line in FIG. 6). Thus, the entirety of the audio signal is compressed, whereby the signal level Vₙ of the entirety of the audio signal can be easily adjusted to not more than the possible output level by software without complicated processing, unlike the case where only part of the audio signal is compressed.

According to the second embodiment, as hereinabove described, the signal level processing portion 24a is configured to compress the gain of the entirety of the audio signal on the basis of the compressibility calculated by the central processing unit 22a. Thus, the sound volume can be easily compressed.

According to the second embodiment, as hereinabove described, the signal level processing portion 24a is configured to compress the entirety of the audio signal such that the maximum value of the signal level after compression reaches the vicinity of the possible output level. Thus, an excessive reduction in outputs (sound volume) from the speakers 5 resulting from excessive compression of the audio signal can be suppressed.

According to the second embodiment, as hereinabove described, the signal level processing portion 24a is configured to compress the entirety of the audio signal such that the signal waveform of the audio signal before compression and the signal waveform of the audio signal after compression have the shapes corresponding to each other. Thus, the proportion of the signal waveform of the audio signal before and after compression is maintained, and hence a change in the characteristics of the audio signal can be suppressed.

### Third Embodiment

The structure of an audio system 100b according to a third embodiment of the present invention is now described with reference to FIGS. 1 and 7. In this third embodiment, only an excess portion (see a shaded area in FIG. 7) of an audio signal whose signal level exceeds a possible output level is compressed in a state where the proportion of a signal waveform is maintained such that the signal level of the excess portion becomes not more than the possible output level, unlike the aforementioned second embodiment in which the entirety of the audio signal is compressed such that the signal level of the entirety of the audio signal becomes not more than the possible output level.

As shown in FIG. 1, according to the third embodiment, a DSP 2b of the audio system 100b includes a peak detector 21 connected to the output of a decoder 1, a central processing unit 22b connected to the output of the peak detector 21, an internal memory 23b connected to the central processing unit 22b, and a signal level processing portion 24b connected to the output of the central processing unit 22b and connected to the output of the decoder 1, similarly to the aforementioned second embodiment. The central processing unit 22b, the internal memory 23b, and the signal level processing portion 24b are examples of the “arithmetic portion”, the “storage portion”, and the “adjusting portion” in the present invention, respectively.

The peak detector 21 is configured to detect a digital value Xₙ of the audio signal (digital signal) output from the decoder 1, similarly to the aforementioned second embodiment. The central processing unit 22b is configured to calculate compressibility C_{L} for compressing the signal level Vₙ of the audio signal to not more than a prescribed possible output level (see a dotted line in FIG. 7) on the basis of the digital value Xₙ detected by the peak detector 21 and values specific to the audio system 100b stored in the internal memory 23b, similarly to the aforementioned second embodiment. The internal memory 23b stores a software program executed by the central processing unit 22b etc. in addition to the values specific to the audio system 100b such as the modulation factor m of a PWM processor 3, a power supply voltage V_{D} input to a D-AMP 4, the impedance Rₙ of each of speakers 5, the efficiency E_{D} of the D-AMP 4, and the maximum value W_{L} of the amount of power that a D-AMP power supply portion 6 can actually output.

According to the third embodiment, the audio system 100b has a DRC (dynamic range compression) function (a function of adjusting the sound volume of sound of relatively small sound volume to be further increased and adjusting the sound volume of sound of relatively large sound volume to be further decreased). The signal level processing portion 24b includes a volume control unit configured to achieve the DRC function. Specifically, the signal level processing portion 24b is configured to change a current setting value B_{old} of the DRC function to a new setting value B_{new} calculated on the basis of the following expression (10) on the basis of the compressibility C_{L} calculated by the central processing unit 22b.

new setting value B_{new}[dB]=current setting value B_{old}[dB]+20 log(√C_{L}) (10)

Thus, according to the third embodiment, the signal level processing portion 24b is configured to compress the excess portion (see the shaded area in FIG. 7) of the audio signal whose signal level exceeds the possible output level on the basis of the compressibility C_{L} calculated by the central processing unit 22b such that the signal level of the excess portion becomes not more than the possible output level, as shown in FIG. 7. In FIG. 7, the signal waveform of the audio signal before compression is indicated by an alternate long and short dash line, and the signal waveform after compression is indicated by a solid line. According to the third embodiment, the signal waveform (see the alternate long and short dash line) of the audio signal before compression and the signal waveform (see the solid line) of the audio signal after compression have curves (sinusoidal curves) of shapes corresponding to each other in the excess portion (see the shaded area), as shown in FIG. 7. In other words, according to the third embodiment, the proportion of the signal waveform of the excess portion of the audio signal is maintained before compression and after compression.

According to the third embodiment, as hereinabove described, the signal level processing portion 24b is configured to compress the excess portion (see the shaded area in FIG. 7) of the audio signal whose signal level Vₙ exceeds the possible output level on the basis of the compressibility C_{L} calculated by the central processing unit 22b such that the signal level Vₙ of the excess portion becomes not more than the possible output level. Thus, a portion other than the excess portion is not compressed, and hence an excessive reduction in the signal level Vₙ resulting from compression of a portion (the portion other than the excess portion) normally not need to be compressed can be suppressed.

According to the third embodiment, as hereinabove described, the signal level processing portion 24b is configured not to compress a non-excess portion of the audio signal whose signal level does not exceed the possible output level and configured to compress the entirety of the excess portion of the audio signal whose signal level exceeds the possible output level. Thus, the non-excess portion of the audio signal whose signal level does not exceed the possible output level is not compressed, and hence a load on the signal level processing portion 24b can be reduced.

According to the third embodiment, as hereinabove described, the signal level processing portion 24b is configured to compress the entirety of the excess portion of the audio signal whose signal level exceeds the possible output level on the basis of the compressibility calculated by the central processing unit 22b such that the signal waveform of the audio signal before compression and the signal waveform of the audio signal after compression have the shapes corresponding to each other. Thus, the proportion of the signal waveform of the audio signal before and after compression is maintained, and hence a change in the characteristics of the audio signal can be suppressed.

The embodiments disclosed this time must be considered as illustrative in all points and not restrictive. The range of the present invention is shown not by the above description of the embodiments but by the scope of claims for patent, and all modifications within the meaning and range equivalent to the scope of claims for patent are further included.

For example, while the audio system outputting and reproducing the audio signal (digital signal) recorded in the BD is shown as the example of the digital electronic device according to the present invention in each of the aforementioned first to third embodiments, the present invention is not restricted to this. The present invention is also applicable to a common digital electronic device such as a home theater system capable of outputting and reproducing a video signal in addition to an audio signal.

While the peak detector detecting the peak value of the signal level of the audio signal (digital signal) is shown as the example of the detecting portion according to the present invention in each of the aforementioned first to third embodiments, the present invention is not restricted to this. According to the present invention, a detecting portion detecting an effective value of the signal level of the audio signal may alternatively be employed. In this case, in order to simplify processing for detecting the effective value, the peak value of the signal level of the audio signal may be detected, and a value obtained by dividing the detected value (peak value) by √2 may be employed as the effective value.

While the values specific to the audio system (digital electronic device) are previously stored in the internal memory (storage portion) in each of the aforementioned first to third embodiments, the present invention is not restricted to this. According to the present invention, a communication interface configured to communicate externally may alternatively be provided in the digital electronic device, and the digital electronic device may alternatively be configured to be capable of update the values stored in the storage portion through the communication interface.

What is claimed is:

1. A digital electronic device comprising:
an output portion outputting a digital signal;
a detecting portion detecting a digital value of the digital signal input to the output portion;
an arithmetic portion calculating a signal level of the digital signal on the basis of the digital value detected by the detecting portion and calculating an adjustment coefficient employed to adjust the signal level that is calculated to not more than a possible output level that the output portion can output; and
an adjusting portion adjusting the digital signal on the basis of the adjustment coefficient calculated by the arithmetic portion such that the signal level becomes not more than the possible output level.

2. The digital electronic device according to claim 1, wherein
the adjustment coefficient includes compressibility employed to compress the signal level to not more than the possible output level, and
the adjusting portion is configured to compress the digital signal on the basis of the compressibility calculated by the arithmetic portion such that the signal level becomes not more than the possible output level.

3. The digital electronic device according to claim 2, further comprising a storage portion storing a value specific to the digital electronic device including a value corresponding to the possible output level, wherein
the arithmetic portion is configured to calculate the signal level on the basis of the digital value detected by the detecting portion and the value specific to the digital electronic device stored in the storage portion and calculate the compressibility employed to compress the signal level that is calculated to not more than the possible output level.

4. The digital electronic device according to claim 3, further comprising:
a PWM conversion portion configured to convert a signal input from the adjusting portion to a PWM signal;
an amplifying portion amplifying a signal input from the PWM conversion portion and outputting the signal to the output portion; and
a power supply portion supplying power to the amplifying portion, wherein
the value specific to the digital electronic device stored in the storage portion includes at least one of a modulation factor of the PWM conversion portion, a power supply voltage input to the amplifying portion, an impedance of the output portion, efficiency of the amplifying portion, and a maximum value of an amount of power that the power supply portion can output.

5. The digital electronic device according to claim 2, wherein
the adjusting portion is configured to compress an excess portion of the digital signal whose signal level exceeds the possible output level on the basis of the compressibility calculated by the arithmetic portion such that the signal level of the excess portion becomes equal to the possible output level.

6. The digital electronic device according to claim 5, wherein
the adjusting portion is configured not to compress a non-excess portion of the digital signal whose signal level does not exceed the possible output level and configured to compress the excess portion of the digital signal whose signal level exceeds the possible output level such that the signal level of the excess portion becomes equal to the possible output level.

7. The digital electronic device according to claim 2, wherein
the adjusting portion is configured to compress an entirety of the digital signal on the basis of the compressibility calculated by the arithmetic portion such that the signal level of the entirety of the digital signal becomes not more than the possible output level.

8. The digital electronic device according to claim 7, wherein
the adjusting portion is configured to compress a gain of the entirety of the digital signal on the basis of the compressibility calculated by the arithmetic portion.

9. The digital electronic device according to claim 7, wherein
the adjusting portion is configured to compress the entirety of the digital signal such that a maximum value of the signal level after compression reaches a vicinity of the possible output level.

10. The digital electronic device according to claim 7, wherein
the adjusting portion is configured to compress the entirety of the digital signal such that a signal waveform of the digital signal before compression and a signal waveform of the digital signal after compression have shapes corresponding to each other.

11. The digital electronic device according to claim 2, wherein
the adjusting portion is configured to compress an excess portion of the digital signal whose signal level exceeds the possible output level on the basis of the compressibility calculated by the arithmetic portion such that the signal level of the excess portion becomes not more than the possible output level.

12. The digital electronic device according to claim 11, wherein
the adjusting portion is configured not to compress a non-excess portion of the digital signal whose signal level does not exceed the possible output level and configured to compress an entirety of the excess portion of the digital signal whose signal level exceeds the possible output level.

13. The digital electronic device according to claim 11, wherein
the adjusting portion is configured to compress an entirety of the excess portion of the digital signal whose signal level exceeds the possible output level on the basis of the compressibility calculated by the arithmetic portion such that a signal waveform of the digital signal before compression and a signal waveform of the digital signal after compression have shapes corresponding to each other.

14. The digital electronic device according to claim 1, further comprising:
an amplifying portion amplifying a signal input from the adjusting portion and outputting the signal to the output portion; and
a power supply portion supplying power to the amplifying portion, wherein
the possible output level includes a value corresponding to a maximum value of an amount of power that the power supply portion can output.

15. A method for adjusting a signal level of a digital signal, comprising steps of:
detecting a digital value of the digital signal;
calculating the signal level of the digital signal on the basis of the digital value that is detected and calculating an adjustment coefficient employed to adjust the signal level that is calculated to not more than a prescribed possible output level; and
adjusting the digital signal on the basis of the adjustment coefficient that is calculated such that the signal level becomes not more than the prescribed possible output level.

16. The method for adjusting a signal level of a digital signal according to claim 15, wherein
the step of calculating the adjustment coefficient includes a step of calculating the signal level of the digital signal on the basis of the digital value that is detected and calculating compressibility employed to compress the signal level that is calculated to not more than the prescribed possible output level, and
the step of adjusting the digital signal includes a step of compressing the digital signal on the basis of the compressibility that is calculated such that the signal level becomes not more than the prescribed possible output level.

17. The method for adjusting a signal level of a digital signal according to claim 16, wherein
the step of calculating the compressibility includes a step of calculating the signal level on the basis of the digital value that is detected and a value specific to a digital electronic device including a value corresponding to the prescribed possible output level that is stored and calculating the compressibility employed to compress the signal level that is calculated to not more than the prescribed possible output level.

18. The method for adjusting a signal level of a digital signal according to claim 16, wherein
the step of compressing the digital signal includes a step of compressing an excess portion of the digital signal whose signal level exceeds the prescribed possible output level on the basis of the compressibility that is calculated such that the signal level of the excess portion becomes equal to the prescribed possible output level.

19. The method for adjusting a signal level of a digital signal according to claim 16, wherein
the step of compressing the digital signal includes a step of compressing an entirety of the digital signal on the basis of the compressibility that is calculated such that the signal level of the entirety of the digital signal becomes not more than the prescribed possible output level.

20. The method for adjusting a signal level of a digital signal according to claim 16, wherein
the step of compressing the digital signal includes a step of compressing an excess portion of the digital signal whose signal level exceeds the prescribed possible output level on the basis of the compressibility that is calculated such that the signal level of the excess portion becomes not more than the prescribed possible output level.
